(19) United States
(12) Patent Application Publication
(10) Pub. No.: US 2017/0084502 A1
(43) Pub. Date: Mar. 23, 2017

(54) LIGHT EMITTING DEVICE, COLOR COORDINATE MEASURING APPARATUS AND COLOR COORDINATE CORRECTION METHOD THEREOF

(71) Applicant: Seoul Semiconductor Co., Ltd., Ansan-si (KR)

(72) Inventors: Gyeong Nam KIM, Ansan-si (KR); Hyuck Jun KIM, Ansan-si (KR)

(21) Appl. No.: 15/366,800

(22) Filed: Dec. 1, 2016

Related U.S. Application Data
(63) Continuation of application No. PCT/KR2016/009582, filed on Aug. 29, 2016.

(30) Foreign Application Priority Data
Sep. 15, 2015 (KR) 10-2015-0130413

(51) Int. Cl. H01L 21/66; H01L 33/48; G01J 3/46; H01L 33/56; H01L 33/62; H01L 33/00; H01L 33/50

(52) U.S. Cl. CPC H01L 22/24; H01L 33/00; H01L 33/486; H01L 33/501; H01L 33/56; H01L 33/508; H01L 33/62; G01J 3/46; H01L 2933/0041

(57) ABSTRACT

A method and apparatus for measuring color coordinates of a light emitting device. The color coordinate measuring apparatus includes a rail on which a substrate is mounted, the substrate having a plurality of light emitting devices (LEDs) formed thereon, a transfer device disposed under the rail and configured to move toward or away from a target region of the substrate, a plurality of electrode pins disposed on the transfer device and configured to respectively contact electrodes of the plurality of light emitting devices in the target region at the same time when the transfer device approaches the target region, a controller configured to sequentially supply electric power to the plurality of electrode pins, and a measurement unit disposed above the rail and configured to be placed above the target region in which the plurality of electrode pins is brought into contact with the electrodes of the plurality of light emitting devices.

### CROSS-REFERENCE TO RELATED APPLICATIONS

This application is a continuation of International Application PCT/KR2016/009582, filed Aug. 29, 2016, and claims priority from and the benefit of Korean Patent Application No. 10-2015-0130413, filed Sep. 15, 2015, which is incorporated by reference for all purposes as if fully set forth herein.

### BACKGROUND

Field

Exemplary embodiments of the disclosure relate to measurement and correction of color coordinates of a light emitting device.

Discussion of the Background

With advantages such as high luminous efficacy and long lifespan, light emitting devices (LEDs) have rapidly replaced a typical lamp lighting apparatus.

The light emitting device is fabricated in a structure wherein a plurality of LED chips is mounted on a rectangular substrate (for example, a lead frame), which in turn is finally cut into individual devices. Before cutting the substrate into individual light emitting devices, an inspection procedure must be performed to confirm whether each of the light emitting devices is normally operated to emit light.

In particular, a white color is most commonly used as a color of a light source for lighting and can be realized through combination of a blue LED chip and phosphors capable of being excited by blue light. This technique is based on a correlation between the spectrum of blue light and a luminous spectrum of the phosphors, and thus is suitable for mass production and can be easily realized.

In one method for realization of white light using phosphors most generally used in the art, a transparent epoxy resin or a silicone resin is mixed with a suitable amount of phosphors to obtain desired color coordinates to prepare a phosphor mixture, which in turn is provided to an LED chip and cured through heat treatment at a predetermined temperature. However, since this method cannot precisely control the number of phosphors per unit volume due to sedimentation and flow of the phosphors, the color coordinate distribution of an LED increases, thereby causing inconsistencies in color among the products in a bin of products.

However, products having poor color coordinates can be removed from the bin of products so as to have a color coordinate bin of products with a consistent color coordinate distribution through correction after measurement of the color coordinates of LEDs.

Korean Patent No. 1059729 discloses an apparatus for measuring LED color coordinates, which is required to recover products having poor color coordinates so as to have a color coordinate bin of good products through correction after measurement of the color coordinates of LEDs. Such a color coordinate measuring apparatus is configured to perform individual measurement of each LED on a substrate. That is, in measurement of each LED, an operation of bringing an electrode pin into contact with an electrode of the corresponding LED to supply electric power for measurement, followed by shifting the electrode pin and a substrate to an adjacent LED, is repeatedly performed for each LED.

For this operation, since an operation of forwardly or backwardly moving the electrode pin with respect to the electrode and an operation of moving the substrates one by one must be repeated and require substantial time consumption in mechanical movement of these components, measurement is very slowly performed. Thus, a great number of facilities have been provided to establish a mass production system and to comply with production speeds of other production lines. This causes significant deterioration in production efficiency.

### SUMMARY

Exemplary embodiments of the disclosure provide an apparatus and method for measuring color coordinates, which are capable of performing rapid measurement of color coordinates of a plurality of light emitting devices on a substrate.

In accordance with one exemplary embodiment of the disclosure, a color coordinate measuring apparatus may include a rail on which a substrate is mounted, the substrate having a plurality of light emitting devices (LEDs) formed thereon, a transfer device disposed under the rail and configured to move toward or away from a target region of the substrate, a plurality of electrode pins disposed on the transfer device and configured to respectively contact electrodes of the plurality of light emitting devices in the target region at the same time when the transfer device approaches the target region, a controller configured to sequentially supply electric power to the plurality of electrode pins, and a measurement unit disposed above the rail and configured to be placed above the target region in which the plurality of electrode pins is brought into contact with the electrodes of the plurality of light emitting devices.

The electrodes of the LEDs may be downward exposure type electrodes, and may be configured such that, as the transfer device approaches the electrodes in an upward direction from a place below the electrodes, the electrode pins may simultaneously contact respective electrodes of the LEDs in the target region. Each of the electrode pins may be independently elastically supported in the upward direction.

The electrodes of the LEDs may be lateral exposure type electrodes, and may be configured such that, as the transfer device approaches the substrate in an upward direction from a place below the substrate and is then moved in a lateral direction, the electrode pins may simultaneously contact respective electrodes of the LEDs in the target region. The transfer device may be provided with a contact block, which supports a lower surface of the substrate to prevent the substrate from sagging when the transfer device approaches the substrate in the upward direction from the place below the substrate, such that the lateral exposure type electrodes are aligned with the electrode pins. Each of the electrode pins may be independently elastically supported in the lateral direction.

The plurality of electrode pins may constitute a conversion module such that the electrode pins are detachably attached to the transfer device.

The plurality of electrode pins and the contact blocks may constitute a conversion module such that the electrode pins are detachably attached to the transfer device.

The transfer device may be provided with a base part to which the conversion module is detachably attached, and the base part may be provided with a printed circuit board (PCB) configured to distribute electric current to each of the electrode pins.

The transfer device may be configured to be transferred in an x-direction parallel to a surface of the substrate, in a y-direction parallel to the surface of the substrate and perpendicular to the x-direction, and in a z-direction perpendicular to the surface of the substrate.

The measurement unit may be configured to be transferred in the x-direction parallel to the surface of the substrate and in the y-direction parallel to the surface of the substrate and perpendicular to the x-direction.

In accordance with another exemplary embodiment of the disclosure, a color coordinate measurement method may include mounting a substrate on a rail, the substrate having a plurality of LEDs formed thereon, dividing the plurality of LEDs on the substrate into a plurality of target regions, placing a measurement unit above the plurality of LEDs in a target region to be measured, bringing a plurality of electrode pins into contact with electrodes of the plurality of LEDs in the target region by moving the plurality of electrode pins upwards from a place below the plurality of LEDs in the target region to be measured, and sequentially measuring color coordinates of the plurality of LEDs in the target region by sequentially supplying electric power to each of the plurality of electrode pins.

The electrodes of the LEDs may be downward exposure type electrodes, and as the plurality of electrode pins approaches the electrodes in an upward direction from a place below the electrodes, the plurality of electrode pins may simultaneously contact respective electrodes of the LEDs in the target region.

The electrodes of the LEDs may be lateral exposure type electrodes, and as the plurality of electrode pins approaches the substrate in an upward direction from a place below the substrate and is then moved in a lateral direction, the plurality of electrode pins may simultaneously contact respective electrodes of the LEDs in the target region. Contact blocks may be moved together with the electrode pins to prevent the substrate from sagging by supporting a lower surface of the substrate when the electrode pins approach the substrate in the upward direction from a place below the substrate, thereby allowing the lateral exposure type electrodes to be aligned with the plurality of electrode pins.

Upon detecting that an LED is not turned on based on measurement results of color coordinates of the plurality of LEDs, the method may further include registering an LED having failed to obtain measurement values. The method may further include disposing the measurement unit above the LED having failed to obtain measurement values, transferring the electrode pins such that an electrode pin different from an electrode pin having been brought into contact with the LED having failed to obtain measurement values among the plurality of electrode pins is brought into contact with an electrode of the LED having failed to obtain measurement values, and measuring color coordinates of the LED having failed to obtain measurement values by supplying electric power to the electrode pin contacting the electrode of the LED having failed to obtain measurement values. Upon detecting that the corresponding LED is not turned on based on measurement results of the color coordinates of the corresponding LED, the method may further include registering the corresponding LED as a defective product.

The method may further include moving the measurement unit to the next target region after completion of measurement moving the electrode pins away from the target region where measurement of the color coordinates is accomplished, and moving the electrode pins to the next target region, followed by moving the plurality of electrode pins from a place below a plurality of LEDs placed in the next target region to contact electrodes of the plurality of LEDs placed in the next target region.

The electrode pins may be transferred in an x-direction parallel to a surface of the substrate, in a y-direction parallel to the surface of the substrate and perpendicular to the x-direction, and in a z-direction perpendicular to the surface of the substrate.

The measurement unit may be transferred in the x-direction parallel to the surface of the substrate and in the y-direction parallel to the surface of the substrate and perpendicular to the x-direction.

In accordance with a further exemplary embodiment of the disclosure, a light emitting device may include a package body having a cavity therein, a light emitting diode chip mounted in the cavity, a resin covering the light emitting diode chip in the cavity, and a phosphor layer placed in the resin and settled on the light emitting diode chip, wherein the phosphor layer has a convex portion or a concave portion on the light emitting diode chip.

The convex portion or the concave portion may be placed in a central region of the light emitting diode chip, without being limited thereto. The concave portion or convex portion may be located at an edge of the light emitting diode chip.

The light emitting device may further include at least two bonding wires bonded to the light emitting diode chip, wherein the concave portion or the convex portion may be disposed between the bonding wires.

In accordance with yet another exemplary embodiment of the disclosure, a color coordinate correction system may include the color coordinate measuring apparatus configured to measure color coordinates of a plurality of light emitting devices formed on a substrate and dispensers configured to respectively eject a phosphor-containing resin and a phosphor-free resin to a light emitting device deviating from a target bin based on color coordinates measured by the measurement unit. The color coordinate measuring apparatus and the dispensers for correction of color coordinates may be integrated into a single system, thereby reducing an operation time for correction of the color coordinates.

According to exemplary embodiments, the color coordinate measuring apparatus may be configured to measure color coordinates of a plurality of LEDs at the same time by sequentially operating the LEDs to emit light after concurrently electrically connecting electrode pins to the plurality of LEDs, thereby enabling very rapid measurement of the color coordinates of the LEDs formed on a substrate by minimizing a mechanical movement trace of the electrode pins and a measurement unit (integrating sphere). Accordingly, the color coordinate measuring apparatus can be suitably applied to a mass production system without introduction of a plurality of color coordinate measuring apparatuses.

The above and other effects will become apparent from the detailed description of the following exemplary embodiments of the disclosure.

### BRIEF DESCRIPTION OF THE DRAWINGS

The above and other aspects, features and advantages of the invention will be more clearly understood from the following detailed description taken in conjunction with the accompanying drawings, in which:

FIG. 1 is a plan view of an exemplary lead frame on which a plurality of LEDs is mounted.

FIG. 2 is a side view with enlarged detail of an exemplary color coordinate measuring apparatus on which a lead frame having downward exposure type electrodes is installed.

FIG. 3 is a diagram illustrating an exemplary movement sequence and movement directions of electrode pins and an exemplary integrating sphere in the color coordinate measuring apparatus of FIG. 2.

FIG. 4 is a side view with enlarged detail of the exemplary color coordinate measuring apparatus on which a lead frame having lateral exposure type electrodes mounted thereon is installed.

FIG. 5 is a diagram illustrating an exemplary movement sequence and movement directions of electrode pins and an integrating sphere in the exemplary color coordinate measuring apparatus of FIG. 4.

FIG. 6 is an exemplary graph depicting a color coordinate distribution of light emitting devices manufactured by the same process.

FIG. 7 is a flowchart illustrating a method of manufacturing a light emitting device according to an exemplary embodiment of the disclosure.

FIG. 8 is a graph depicting an exemplary method of correcting color coordinates according to the disclosure.

FIG. 9 to FIG. 14 are sectional views illustrating an exemplary method of manufacturing a light emitting device according to the disclosure.

FIG. 15 is a sectional view of a light emitting device according to another exemplary embodiment of the disclosure.

FIG. 16 is a flowchart illustrating another exemplary embodiment of a method of manufacturing a light emitting device according to the disclosure.

FIG. 17, FIG. 18, FIG. 19, FIG. 20, FIG. 21, FIG. 22, and FIG. 23 are sectional views illustrating still another exemplary method of manufacturing a light emitting device according to the disclosure.

FIG. 24 is a sectional view of an exemplary embodiment of a light emitting device manufactured without correction of color coordinates.

FIG. 25 is a sectional view of an exemplary embodiment of a light emitting device subjected to correction of color coordinates by adding phosphors.

FIG. 26 is a sectional view of another exemplary embodiment of a light emitting device subjected to correction of color coordinates by adding phosphors.

### DETAILED DESCRIPTION OF THE ILLUSTRATED EMBODIMENTS

Hereinafter, exemplary embodiments of the disclosure will be described in detail with reference to the accompanying drawings. The following embodiments are provided by way of example so as to fully convey the spirit of the disclosure to those skilled in the art to which the disclosure pertains. Accordingly, the disclosure is not limited to the embodiments disclosed herein and can also be implemented in different forms. In the drawings, widths, lengths, thicknesses, and the like of elements can be exaggerated for clarity and descriptive purposes. Throughout the specification, like reference numerals denote like elements having the same or similar functions.

In the following description, for the purposes of explanation, numerous specific details are set forth in order to provide a thorough understanding of various exemplary embodiments. It is apparent, however, that various exemplary embodiments may be practiced without these specific details or with one or more equivalent arrangements. In other instances, well-known structures and devices are shown in block diagram form in order to avoid unnecessarily obscuring various exemplary embodiments.

Unless otherwise specified, the illustrated exemplary embodiments are to be understood as providing exemplary features of varying detail of various exemplary embodiments. Therefore, unless otherwise specified, the features, components, modules, layers, films, panels, regions, and/or aspects of the various illustrations may be otherwise combined, separated, interchanged, and/or rearranged without departing from the disclosed exemplary embodiments. Further, in the accompanying figures, the size and relative sizes of layers, films, panels, regions, etc., may be exaggerated for clarity and descriptive purposes. When an exemplary embodiment may be implemented differently, a specific process order may be performed differently from the described order. For example, two consecutively described processes may be performed substantially at the same time or performed in an order opposite to the described order. Also, like reference numerals denote like elements.

When an element or layer is referred to as being “on,” “connected to,” or “coupled to” another element or layer, it may be directly on, connected to, or coupled to the other element or layer or intervening elements or layers may be present. When, however, an element or layer is referred to as being “directly on,” “directly connected to,” or “directly coupled to” another element or layer, there are no intervening elements or layers present. Further, the DR1-axis, the DR2-axis, and the DR3-axis are not limited to three axes of a rectangular coordinate system, and may be interpreted in a broader sense. For example, the DR1-axis, the DR2-axis, and the DR3-axis may be perpendicular to one another, or may represent different directions that are not perpendicular to one another. For the purposes of this disclosure, “at least one of X, Y, and Z” and “at least one selected from the group consisting of X, Y, and Z” may be construed as X only, Y only, Z only, or any combination of two or more of X, Y, and Z, such as, for instance, XYZ, XYY, YZ, and ZZ. As used herein, the term “and/or” includes any and all combinations of one or more of the associated listed items.

Although the terms “first,” “second,” etc. may be used herein to describe various elements, components, regions, layers, and/or sections, these elements, components, regions, layers, and/or sections should not be limited by these terms. These terms are used to distinguish one element, component, region, layer, and/or section from another element, component, region, layer, and/or section. Thus, a first element, component, region, layer, and/or section discussed below could be termed a second element, component, region, layer, and/or section without departing from the teachings of the disclosure.

Spatially relative terms, such as “beneath,” “below,” “lower,” “above,” “upper,” and the like, may be used herein for descriptive purposes, and, thereby, to describe one element or feature's relationship to another element(s) or feature(s) as illustrated in the drawings. Spatially relative terms are intended to encompass different orientations of an apparatus in use, operation, and/or manufacture in addition to the orientation depicted in the drawings. For example, if the apparatus in the drawings is turned over, elements described as “below” or “beneath” other elements or features would then be oriented “above” the other elements or features. Thus, the exemplary term “below” can encompass both an orientation of above and below. Furthermore, the apparatus may be otherwise oriented (e.g., rotated 90 degrees or at other orientations), and, as such, the spatially relative descriptors used herein interpreted accordingly.

The terminology used herein is for the purpose of describing particular embodiments and is not intended to be limiting. As used herein, the singular forms, “a,” “an,” and “the” are intended to include the plural forms as well, unless the context clearly indicates otherwise. Moreover, the terms “comprises,” “comprising,” “includes,” and/or “including,” when used in this specification, specify the presence of stated features, integers, steps, operations, elements, components, and/or groups thereof, but do not preclude the presence or addition of one or more other features, integers, steps, operations, elements, components, and/or groups thereof.

Various exemplary embodiments are described herein with reference to sectional illustrations that are schematic illustrations of idealized exemplary embodiments and/or intermediate structures. As such, variations from the shapes of the illustrations as a result, for example, of manufacturing techniques and/or tolerances, are to be expected. Thus, exemplary embodiments disclosed herein should not be construed as limited to the particular illustrated shapes of regions, but are to include deviations in shapes that result from, for instance, manufacturing. For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place. Thus, the regions illustrated in the drawings are schematic in nature and their shapes are not intended to illustrate the actual shape of a region of a device and are not intended to be limiting.

Unless otherwise defined, all terms (including technical and scientific terms) used herein have the same meaning as commonly understood by one of ordinary skill in the art to which this disclosure is a part. Terms, such as those defined in commonly used dictionaries, should be interpreted as having a meaning that is consistent with their meaning in the context of the relevant art and will not be interpreted in an idealized or overly formal sense, unless expressly so defined herein.

Referring to FIG. 1, a plurality of LEDs 12 are mounted on a substrate, that is, a lead frame 10, to be arranged in a matrix at regular intervals in the x-direction and in the y-direction, that is, in the longitudinal direction and in the transverse direction. Conventionally, since the color coordinates are measured by supplying electric power to electrodes of the LEDs after the electrode pins are brought into contact with the electrodes of the LEDs one by one, it is necessary to move the electrode pins 8the times and to move an integrating sphere or the substrate 8ime times.

Conversely, according to exemplary embodiments of the disclosure, plural electrode pins are simultaneously brought into contact with plural LEDs and electric power is sequentially supplied to the LEDs to measure the color coordinates of the LEDs, thereby enabling significant reduction in the number of movement times of the electrode pins and the integrating sphere.

For example, referring to FIG. 1, when an operation of simultaneously bringing the electrode pins into contact with four LEDs in a target region a1 and then simultaneously measuring the color coordinates of the four LEDs, followed by simultaneously bringing the electrode pins into contact with four LEDs in the next target region a2 and then simultaneously measuring the color coordinates of the four LEDs is repeated, the number of movement times of the electrode pins can be reduced to ¼ the number of movement times in the conventional technique and the number of movement times of the integrating sphere or the substrate can also be reduced to ¼ the number of movement times in the conventional technique.

Measurement of the color coordinates of plural LEDs by sequentially supplying electric power to the LEDs takes about 0.1 seconds for one LED. On the contrary, an operation of withdrawing the electrode pins and then bringing the electrode pins into contact with other LEDs adjacent to the previous LEDs takes at least 1 second. Accordingly, the technique of simultaneously bringing the electrode pins into contact with four LEDs, followed by measuring the color coordinates of the four LEDs takes ¼ the time of the conventional technique.

Although measurement of the color coordinates is performed by applying electric power after the electrode pins are simultaneously brought into 4 LEDs in the above example, measurement of the color coordinates can be performed by setting a target region b1, c1, or d1 in various ways such that the electrode pins are simultaneously brought into contact with, for example, 6, 8, or 9 LEDs. That is, it is possible to measure the color coordinates of a plurality of LEDs at the same time without separate mechanical transfer of the plurality of LEDs so long as the plurality of LEDs can be included in a measurement inlet area of the integrating sphere which measures the color coordinates.

As such, the number of measurement times of the color coordinates can be suitably set in consideration of the measurement inlet area of the integrating sphere and the number of LEDs arranged on the lead frame 10 in each of the longitudinal and transverse directions.

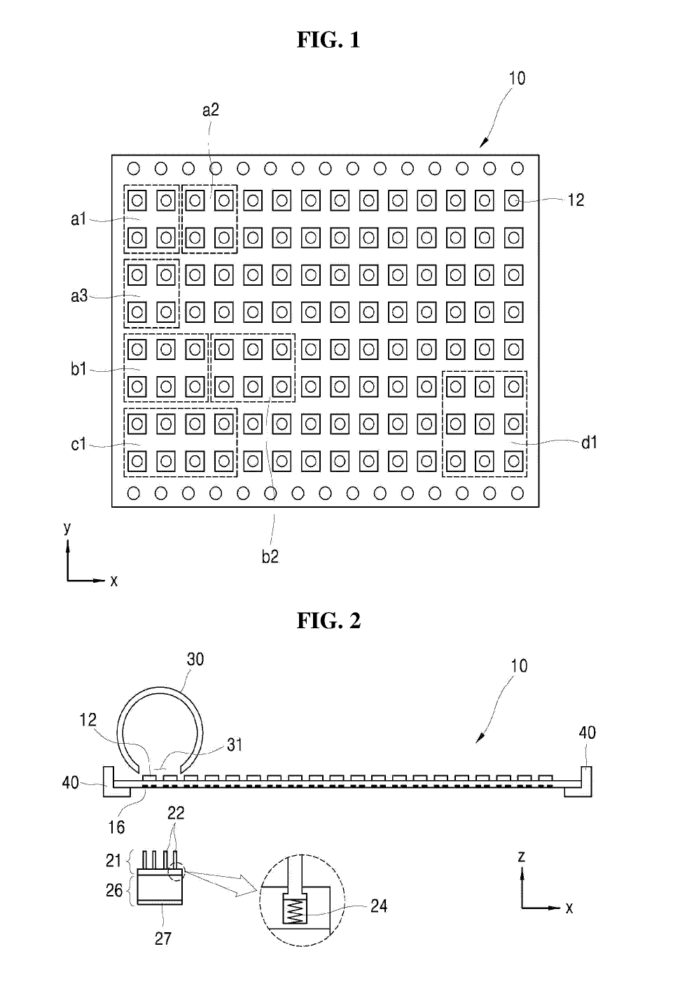

As shown in FIG. 2, both edges of a lead frame 10 having a plurality of LEDs 12 mounted thereon are placed on a rail 40 such that the lead frame 10 can be aligned on the rail 40. For alignment of the lead frame, the rail 40 has step portions such that the lead frame can be aligned inside the step portion on the rail, but is not limited thereto.

Referring to FIG. 2, the LEDs mounted on the lead frame include downward exposure type electrodes 16. For connection to such electrodes 16 of the LEDs, electrode pins 22 are moved upwards from a place below the electrodes 16 to approach the electrodes.

Although FIG. 2 shows a structure wherein the electrode pins can be simultaneously connected to two LEDs, it should be understood that this structure is the simplest structure illustrated only for convenience of description and the disclosure is not limited thereto. The electrode pins 22 capable of being connected to two LEDs are installed on a conversion module 21. Each of the electrode pins 22 is elastically supported by an elastic member such as a spring 24. Thus, when force is applied to the electrode pin in a downward direction, the electrode pin is moved downwards. The conversion module 21 is detachably mounted on a base part 26. The base part 26 is provided with a PCB 27 configured to distribute electric power to each of the electrode pins 22 in the conversion module 21. The structure wherein the conversion module 21 including the electrode pins is detachably mounted on the base part 26 allows replacement of the electrode pins and the springs due to frequent contact and abrasion, and replacement of the conversion module 21 in order to adjust the number of electrode pins to be simultaneously brought into contact with LEDs.

The conversion module 21 and the base part 26 constitute a contactor 20.

The base part 26 of the contactor 20 is installed on a transfer device (not shown) to move together with the transfer device. The transfer device may be a stepper motor or a linear motor which can be moved in the x-direction, the y-direction, and the z-direction. The transfer device is not limited thereto and may be selected from various transfer devices allowing displacement control.

As a measurement unit, an integrating sphere 30 is placed on a substrate 10 and can be moved in the x-direction and the y-direction. A measurement inlet 31 of the integrating sphere has an area covering all of a plurality of LEDs (two LEDs in this exemplary embodiment), which are target LEDs to be measured.

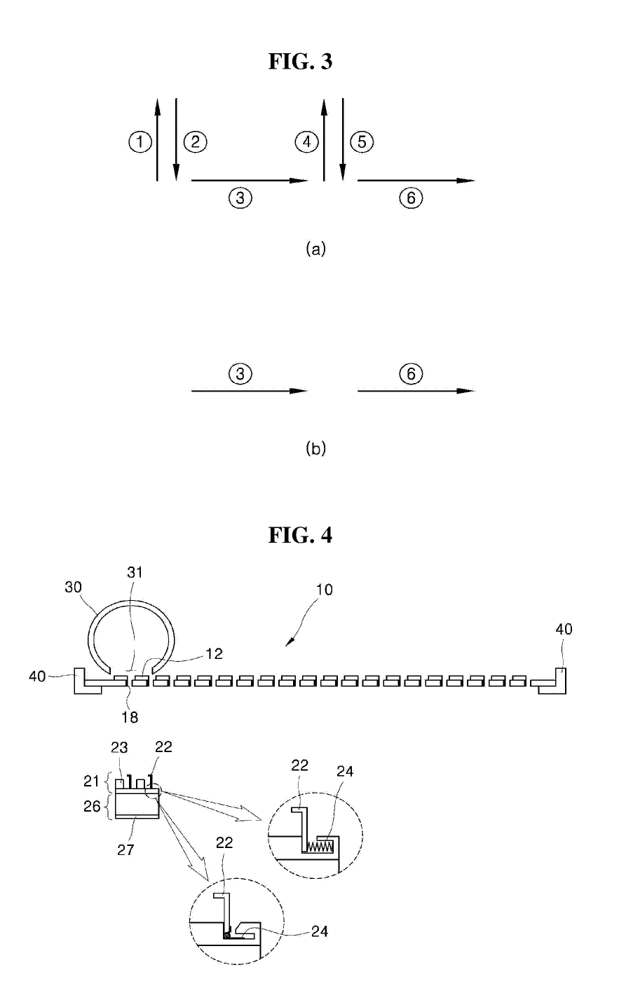

Next, a measurement method using the color coordinate measuring apparatus of FIG. 2 will be described with reference to FIG. 2 and FIG. 3. First, for measurement of color coordinates of LEDs, one lead frame 10 is transferred from a magazine on which a plurality of lead frames each having LEDs mounted thereon is placed, and mounted on the rail 40. The lead frame 10 is placed inside the step portions on the rail 40 to be aligned thereon.

Then, the contactor 20 is transferred to a place below LEDs in a target region. Such movement is performed by x-direction and y-direction conveying units of the transfer device.

Then, the transfer device lifts the contactor 20 in Direction \textcircled{1} corresponding to the z-direction such that the electrode pins 22 are brought into contact with electrodes 16. Here, since the electrode pins 22 are elastically supported in the upward direction, an upper end of each of the electrode pins 22 can be displaced downwards as soon as the electrode pins 22 contact the electrodes 16. Thus, even in the case where plural electrode pins have tolerance therebetween and there is a height difference between the electrodes due to sagging of the lead frame 10 under the weight thereof, the electrode pins can be securely brought into contact with the electrodes of all of the LEDs in the target region. That is, as the transfer device upwardly moves the contactor 20 in Direction \textcircled{1} by a predetermined displacement, the electrode pins 22 lift the lead frame sagging under the electrodes such that the lead frame becomes flat. Further, since the electrode pins can be moved downwards while being elastically supported upwards, the electrode pins can securely contact all of the electrodes which can have a height difference therebetween.

With the electrode pins 22 contacting the electrodes 16 through movement of the contactor 10 in Direction \textcircled{1}, electric power is sequentially supplied to the LEDs. Application of electric power is performed at a time interval of 0.1 seconds or less. When the LEDs are operated to emit light through application of electric power, the color coordinates of the LEDs are measured by the integrating sphere 30.

When measurement of the color coordinates of the LEDs in the target region is completed, the transfer device lowers the contactor in Direction \textcircled{2} and moves the contactor to the next target region. During movement of the contactor towards the next target region in Direction \textcircled{3}, the integrating sphere is also moved in Direction \textcircled{3}.

Such an operation is repeated. That is, the transfer device lifts the contactor 20 in Direction \textcircled{4} corresponding to the z-direction such that the electrode pins 22 are brought into contact with the electrodes 16. Then, electric power is sequentially supplied to the LEDs and when the LEDs are operated to emit light through application of electric power, the color coordinates of the LEDs are measured by the integrating sphere 30.

When measurement of the color coordinates of the LEDs in the target region is completed, the transfer device lowers the contactor 20 in Direction \textcircled{5} and moves the contactor to the next target region adjacent to the target region. During movement of the contactor towards the next target region in Direction \textcircled{6}, the integrating sphere is also moved in Direction \textcircled{6}.

When measurement of the color coordinates of the LEDs in all of the target regions on the substrate is completed in this manner, the substrate is transferred to the next process.

The measurement method according to the exemplary embodiment may include re-measuring the color coordinates of LEDs having failed to obtain measurement values before the substrate having completed measurement of color coordinates is transferred to the next process.

To this end, the color coordinate measuring apparatus according to the exemplary embodiment is configured to perform a process of registering a location of an LED having failed to obtain measurement values upon determining that the LED is not turned on after completion of sequential measurement on the color coordinates of the plurality of LEDs.

Upon completion of measurement of the color coordinates of the LEDs in all of the target regions on the substrate, if it is detected that there is an LED having failed to obtain measurement values, the measurement unit 30 is moved to a place above the LED having failed to obtain the measurement values, and the electrode pins are moved such that an electrode pin different from an electrode pin having been brought into contact with the LED having failed to obtain measurement values among the plurality of electrode pins is brought into contact with an electrode of the LED having failed to obtain measurement values. Then, the color coordinates of the LED having failed to obtain measurement values are measured by supplying electric power to the electrode pin contacting the electrode of the LED having failed to obtain measurement values.

Here, if it is detected based on the measurement result that the corresponding LED still does not emit light, it can be determined that the corresponding LED is a defective product. Conversely, if it is detected based on the measurement result that the LED is turned on to emit light and the coordinates of the LED is normally measured, it can be determined that there is a need to overhaul the electrode pin having contacted the LED in failure of measurement.

Although the integrating sphere 30 and the contactor 20 are illustrated as moving in the x and y-directions (Directions \textcircled{3} and \textcircled{6} in FIG. 3) in the above exemplary embodiment, it should be understood that these movements are relative and it is not necessary for the integrating sphere 30 and the contactor 20 to move in the x and y-directions (Directions \textcircled{3} and \textcircled{6} in FIG. 3). For example, when the rail 40 on which the lead frame 10 is mounted is moved in the x and y-directions (opposite to Directions \textcircled{3} and \textcircled{6} in FIG. 3) without movement of the integrating sphere 30 and the contactor 20 in the x and y-directions, it is possible to measure the color coordinates. Such a transfer direction can be realized in consideration of the internal space of the color coordinate measuring apparatus, the kind and structure of the transfer device, and the like.

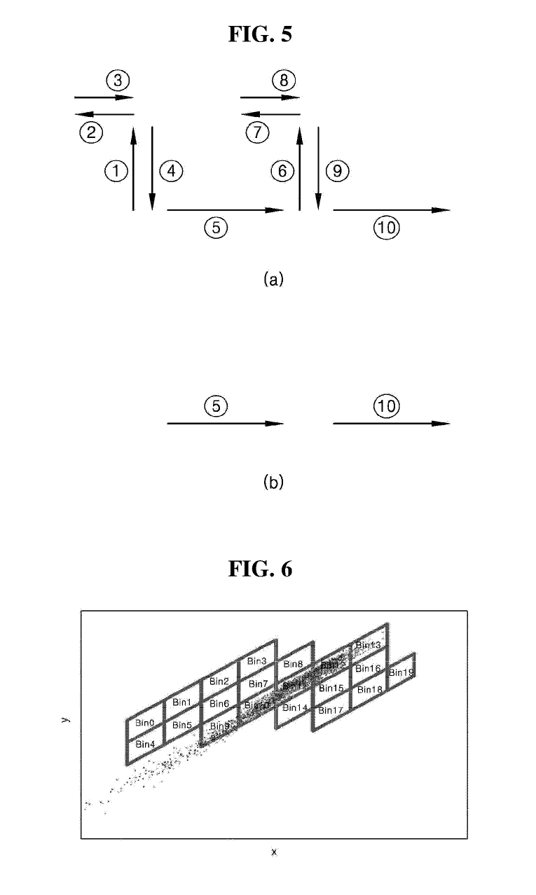

In FIG. 4, the LEDs mounted on the lead frame include lateral exposure type electrodes. Thus, this exemplary embodiment differs from the above exemplary embodiment in terms of a direction of transferring the electrode pins so as to contact such electrodes. The following description will focus on this feature of this exemplary embodiment and descriptions of repeated features will be minimized or omitted.

A lead frame 10 is placed and aligned on a rail 40 subjected to positional alignment.

Referring to FIG. 4, the LEDs mounted on the lead frame include lateral exposure type electrodes 18. For connection to such electrodes 18 of the LEDs, electrode pins 22 are moved upwards from a place below the electrodes 16 to approach the electrodes and are then moved in a lateral direction to contact the electrodes 18.

FIG. 4 also shows the structure wherein the electrode pins can be simultaneously connected to two LEDs. The electrode pins 22 to be connected to the lateral exposure type electrodes 18 have an “L” shape. In the “L” shape of the electrode pins, a horizontal section is much shorter than a vertical section thereof. Since there can be a problem of interference between the electrode pin and the lead frame if the horizontal section of the electrode pin is too long, the horizontal section of the electrode pin has as short a length as possible so long as contact between the electrode pin and an electrode of an LED is secured. The electrode pins 22 are installed on a conversion module 21. Each of the electrode pins 22 is elastically supported by an elastic member such as a spring 24. The elastic member may be realized by a coil spring or a twisted spring. Alternatively, the electrode pins 22 may be formed of an elastic material. For example, the electrode pin 22 may be formed of an elastic material, which allows the vertical section of the electrode pin 22 to be elastically deformed when force is applied to the horizontal section of the electrode pin in the lateral direction. Thus, when force is applied to the horizontal section of the electrode pin in the horizontal direction, the electrode pin can be deformed in an opposite direction to the direction in which force is applied to the electrode pin.

The conversion module 21 is provided with contact blocks 23. When the conversion module 21 is lifted by the transfer device to approach the lead frame, the contact blocks 23 support a lower surface of the lead frame. This structure prevents the lead frame having a thin thickness and a wide area from sagging when the lead frame is mounted on the rail 40. As described below, this structure allows the electrode pins 22, which will be brought into contact with the electrodes 18 in the lateral direction, to be flush with the electrodes 18, whereby the electrode pins can be connected to the electrodes in place.

A base part 26 of the contactor 20 provided with the conversion module 21 is installed on a transfer device (not shown) and can be moved in the x-direction, the y-direction, and the z-direction. Further, as a measurement unit, an integrating sphere 30 is placed on a substrate 10 and can be moved in the x-direction and the y-direction.

Next, a measurement method using the color coordinate measuring apparatus of FIG. 4 will be described with reference to FIG. 4 and FIG. 5. First, for measurement of color coordinates of LEDs, one lead frame 10 is transferred from a magazine on which a plurality of lead frames each having LEDs mounted thereon is placed, and mounted on the rail 40 subjected to positional alignment. The lead frame 10 is placed inside the step portions on the rail 40 to be aligned thereon.

Then, the contactor 20 is transferred to a place below LEDs in a target region. Such movement is performed by x-direction and y-direction conveying units of the transfer device.

Then, the transfer device lifts the contactor 20 in Direction \textcircled{1} corresponding to the z-direction. Here, the contact blocks 23 of the conversion module 21 contact the lower surface of the lead frame 10 to support the lead frame. Particularly, when the transfer device is completely moved in Direction \textcircled{1}, the contact blocks 23 support the lead frame sagging due to the weight thereof, thereby relieving displacement of the lead frame caused by sagging of the lead frame. As sagging of the lead frame is relieved, electrodes 18 of the LEDs mounted on the lead frame become flush with the horizontal sections of the electrode pins 22. Then, the transfer device is moved in Direction \textcircled{2} corresponding to the x-direction such that the electrode pins 22 are brought into contact with the electrodes 18 in the lateral direction. Here, since the electrode pins 22 are elastically supported or formed of an elastic material, the horizontal section of each of the electrode pins 22 can be displaced in the lateral direction as soon as the electrode pins 22 contact the electrodes 18. Thus, even in the case where the plural electrode pins have tolerance therebetween, the electrode pins can be securely brought into contact with the electrodes of all of the LEDs in the target region. That is, as the transfer device upwardly moves the contactor 20 in Direction \textcircled{1} by a predetermined displacement, the contact blocks 23 lift the lead frame such that the lead frame has a horizontal plane, and as the electrode pins are moved in Direction \textcircled{2} by a predetermined displacement while being elastically supported, the electrode pins can securely contact all of the electrodes.

With the electrode pins 22 contacting the electrodes 18, electric power is sequentially supplied to the LEDs. Application of electric power is performed at a time interval of 0.1 seconds or less. When the LEDs are operated to emit light through application of electric power, the color coordinates of the LEDs are measured by the integrating sphere 30.

When measurement of the color coordinates of the LEDs in the target region is completed, the transfer device laterally withdraws the contactor 20 in Direction \textcircled{3} and then lowers the contactor in Direction \textcircled{4}. Then, the transfer device moves the contactor to the next target region adjacent to the previous target region. During movement of the contactor towards the next target region in Direction \textcircled{5}, the integrating sphere is also moved in Direction \textcircled{5}.

Such an operation is repeated. That is, the transfer device lifts the contactor 20 in Direction \textcircled{6} corresponding to the z-direction such that the contact blocks 23 support the lead frame, and is moved in Direction \textcircled{7} corresponding to the x-direction such that the electrode pins 22 are brought into contact with the electrodes 18. Then, electric power is sequentially supplied to the LEDs and when the LEDs are operated to emit light through application of electric power, the color coordinates of the LEDs are measured by the integrating sphere 30.

When measurement of the color coordinates of the LEDs in the target region is completed, the transfer device withdraws the contactor in Direction \textcircled{8}, lowers the contactor in Direction \textcircled{9}, and then moves the contactor to the next target region adjacent to the previous target region. During movement of the contactor towards the next target region in Direction \textcircled{10}, the integrating sphere is also moved in Direction \textcircled{10}.

When measurement of the color coordinates of the LEDs in all of the target regions on the substrate is completed in this manner, the substrate is transferred to the next process.

As in the above exemplary embodiment, the measurement method according to the exemplary embodiment may include re-measuring the color coordinates of LEDs having failed to obtain measurement values.

Although the integrating sphere 30 and the contactor 20 are illustrated as moving in the x and y-directions (Directions \textcircled{2}, \textcircled{3}, \textcircled{5}, \textcircled{8}, \textcircled{9} and \textcircled{10} in FIG. 5) in this exemplary embodiment, it should be understood that these movements are relative and it is not necessary for the integrating sphere 30 and the contactor 20 to move in the x and y-directions (Directions \textcircled{2}, \textcircled{3}, \textcircled{5}, \textcircled{8}, \textcircled{9} and \textcircled{10} in FIG. 5). For example, when the rail 40 on which the lead frame 10 is placed is moved in the x and y-directions (opposite to Directions \textcircled{2}, \textcircled{3}, \textcircled{5}, \textcircled{8}, \textcircled{9} and \textcircled{10} in FIG. 5) without movement of the integrating sphere 30 and the contactor 20 in the x and y-directions, it is possible to measure the color coordinates. The rail 40 on which the lead frame 10 is placed can be moved in the x and y-directions (opposite to Directions \textcircled{2}, \textcircled{3}, \textcircled{5}, \textcircled{8}, \textcircled{9} and \textcircled{10} in FIG. 5), and the contactor 20 can be moved in the x-direction (in Directions \textcircled{2}, \textcircled{3}, \textcircled{8} and \textcircled{9} in FIG. 5). Such a transfer direction can be realized in consideration of the internal space of the color coordinate measuring apparatus, the kind and structure of the transfer device, and the like.

Products having poor color coordinates can be recovered so as to have a color coordinate bin of good products through correction after measurement of the color coordinates of LEDs by the color coordinate measuring apparatus. The following description will focus on correction of the color coordinates of the light emitting device including a light emitting diode chip.

FIG. 6 shows a color coordinate distribution of a plurality of light emitting devices manufactured using blue light emitting diode chips and yellow phosphors. Rectangular boxes on the color coordinates are target ranges of desired color coordinates, as represented by bin codes.

Since one kind of yellow phosphor is used, the light emitting devices emit light having color coordinates distributed from a portion at which blue light is relatively strong to a portion at which yellow light is relatively strong. Among these light emitting devices having such a color coordinate distribution, light emitting devices in the target bin are classified as good products and the remaining light emitting devices are classified as poor products.

Referring to FIG. 7, in the method of manufacturing a light emitting device according to one exemplary embodiment, the first step 120 is a process of forming a first resin containing phosphors in a cavity of a package body on which a light emitting diode chip is mounted. A plurality of package bodies may be provided to one lead frame. In this embodiment, the first resin is formed in the cavity and a curing process is omitted in the first step 110.

In the second step 120, the color coordinates of the light emitting device are measured. The color coordinates are measured using the color coordinate measuring apparatus described above. Here, the second step 120 may be performed after a predetermined period of time for which the phosphors of the first resin settle around the light emitting diode chip. For example, the second step 120 may be performed about 30 minutes to 1 hour after completion of the first step 110.

In the third step 130, a second resin containing or free from phosphors may be mixed with the first resin to correct the measured color coordinates. If the color coordinates of the light emitting device deviate from a target bin, the second resin containing or free from phosphors may be mixed with the first resin in order to correct the color coordinates.

In the fourth step 140, the first and second resins are cured, thereby completing formation of a wavelength conversion part.

According to this exemplary embodiment, the color coordinates of the light emitting device having the first resin are measured without curing the first resin, followed by curing the first resin after correction of the color coordinates of the light emitting device deviating from the target bin, thereby improving yield of the light emitting device.

In order to correct the color coordinates, the second resin containing the phosphors or free from phosphors may be ejected onto the first resin using a dispenser. The above color coordinate measuring apparatus and a color coordinate correction apparatus such as the dispenser may be integrated into a single color coordinate correction system. Here, a dispenser for ejecting the second resin containing the phosphors and a dispenser for ejecting the second resin free from phosphors may be separately provided.

Referring to FIG. 7 to FIG. 14, the method of manufacturing a light emitting device according to the exemplary embodiment will be described in more detail.

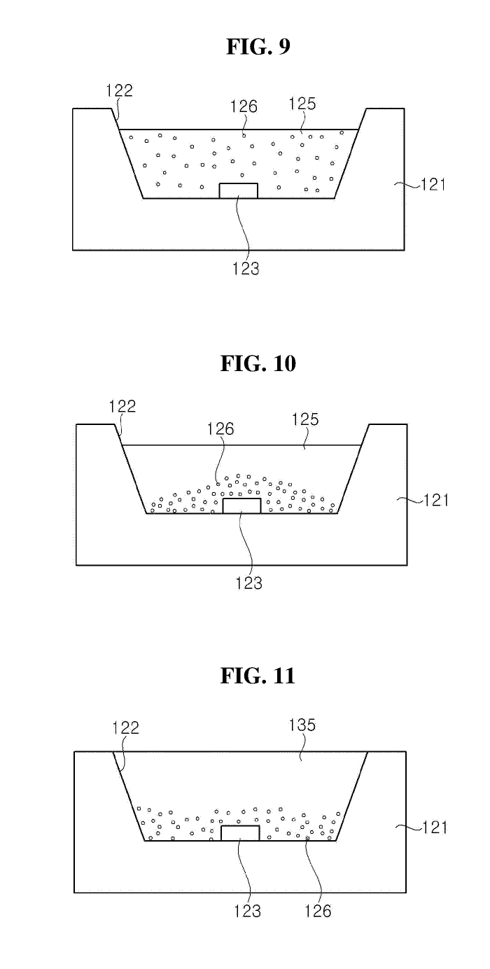

Referring to FIG. 7 and FIG. 9, a first resin 125 is formed on a light emitting diode chip 123 mounted on a package body 121. The package body 121 may have a cavity 122 and the light emitting diode chip 123 may be mounted on a bottom surface of the cavity 122. The package body 121 includes lead electrodes (not shown) and the light emitting diode chip 123 is electrically connected to the lead electrodes.

The first resin 125 may be formed to a predetermined height in the cavity 122. That is, the first resin 125 may be formed so as not to completely fill the cavity 122.

The first resin 125 may be formed by applying a molding resin containing first phosphors 126 in the cavity 122 of the package body 121 using a dispenser. It should be understood that the first resin 125 can be formed in the cavity 122 using a variety of molding methods. The first resin 125 covers the light emitting diode chip 123.

Referring to FIG. 7 and FIG. 10, after the first phosphors 126 settle around the light emitting diode chip 123 for a predetermined period of time, the light emitting diode chip 123 is operated in order to measure the color coordinates thereof. Accordingly, the degree of deviation of the color coordinates of the light emitting device from a target bin can be confirmed.

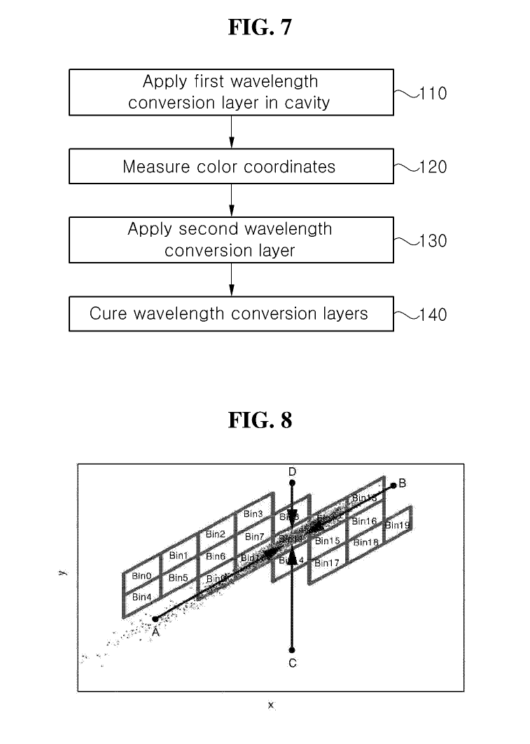

Referring to FIG. 7, FIG. 8 and FIG. 11, if the color coordinates of the light emitting device deviate from the target bin, a second resin free from phosphors may be mixed with the first resin 125 (see FIG. 10). If the measured color coordinates are placed at point B, the second resin free from phosphors may be mixed with the first resin to reduce the concentration of phosphors 126 around the light emitting diode chip 123 such that the color coordinates of the light emitting device can be shifted into the target bin.

Here, the second resin may be mixed with the first resin such that the cavity 122 is completely filled with the wavelength conversion part. In addition, the concentration of the first phosphors 126 gradually decreases from the light emitting diode chip 123 to an upper surface of the resin mixture.

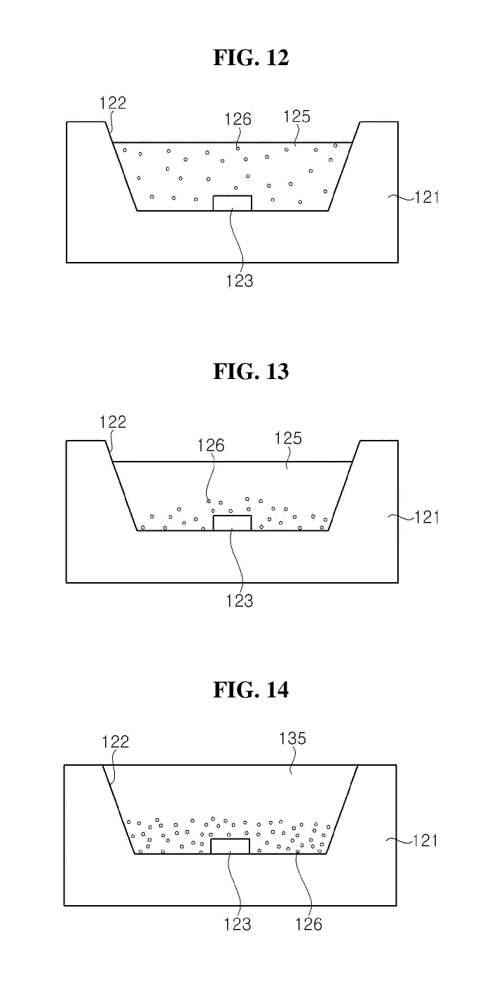

Referring to FIG. 7 and FIG. 12, a first resin 125 is formed on a light emitting diode chip 123 mounted on a package body 121. The package body 121 may have a cavity 122 and the light emitting diode chip 123 may be mounted on a bottom surface of the cavity 122. The package body 121 includes lead electrodes (not shown) and the light emitting diode chip 123 is electrically connected to the lead electrodes.

The first resin 125 may be formed by applying a molding resin containing first phosphors 126 in the cavity 122 of the package body 121 using a dispenser. It should be understood that the first resin 125 can be formed in the cavity 122 using a variety of molding methods. The first resin 125 covers the light emitting diode chip 123.

Referring to FIG. 7 and FIG. 13, after the first phosphors 126 settle around the light emitting diode chip 123 for a predetermined period of time, the light emitting diode chip 123 is operated in order to measure the color coordinates thereof. Accordingly, the degree of deviation of the color coordinates of the light emitting device from a target bin can be confirmed.

Referring to FIG. 7, FIG. 8 and FIG. 14, if the color coordinates of the light emitting device deviate from the target bin, a second resin containing phosphors may be mixed with the first resin 125 (see FIG. 13) to form a wavelength conversion part 135. If the measured color coordinates are placed at point A, the second resin containing the phosphors may be mixed with the first resin to increase the concentration of the first phosphors 126 around the light emitting diode chip 123 such that the color coordinates of the light emitting device can be shifted into the target bin. Here, the phosphors contained in the second resin may be the same or different kind of phosphor from the first phosphors 126 (see FIG. 13) of the first resin 125 (see FIG. 13).

As described above, the color coordinates of the light emitting device are measured without curing the first resin, and if it is determined that the color coordinates deviate from the target bin, curing may be performed after the molding resin containing or free from phosphors is mixed with the first resin to correct the color coordinates, thereby improving yield of the light emitting device.

If the color coordinates measured in the second step 120 are placed at point C or D, a molding resin containing phosphors suitable for correction of the color coordinates may be mixed with the first resin. When the first resin contains two or more kinds of phosphors, the color coordinates can be generally placed at point C or D deviating from the target bin. In this case, the color coordinates may be shifted into the target bin by adjusting the concentration ratio of the phosphors used in the first resin and in the other molding resin or by mixing a different kind of phosphors from the phosphors of the first resin with the phosphors of the first resin.

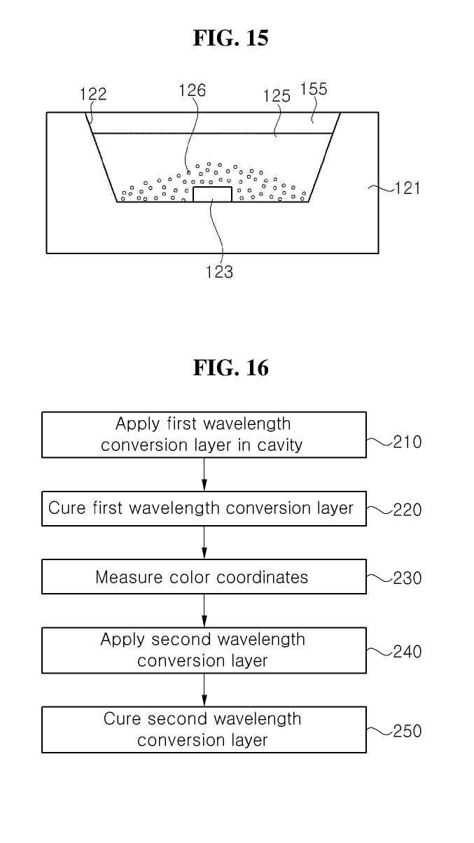

Referring to FIG. 15, a light emitting device according to another exemplary embodiment of the disclosure include a first resin 125 formed to a predetermined height of a cavity 122 of a package body 121 on which a light emitting diode chip 123 is mounted. The first resin 125 contains first phosphors 126.

The color coordinates of the light emitting device are measured without curing the first resin 125. After formation of the first resin 125 of the light emitting device, the first phosphors 126 may settle around the light emitting diode chip 123 for a predetermined period of time.

If the measured color coordinates are placed in a target bin, the first resin 125 is cured without a separate correction process. After curing of the first resin 125, a molding part 155 may be additionally formed using a silicone resin or the like on the first resin 125. The molding part 155 may completely fill the cavity 122 so as to be coplanar with an upper surface of the package body 121.

In the method of manufacturing the light emitting device according to this exemplary embodiment, when the color coordinates are placed in the target bin in measurement of the color coordinates, the molding part 155 is formed on the first resin 125. However, it should be understood that other implementations are also possible and the molding part 155 can be omitted.

Referring to FIG. 16, in the method of manufacturing a light emitting device according to this exemplary embodiment, the first step 210 is a process of forming a first resin in a cavity of a package body on which a light emitting diode chip is mounted. Here, the first resin may fill the cavity to a predetermined height. That is, an upper region of the cavity may be exposed from the first resin.

In the second step 220, the first resin may be subjected to semi-curing. Here, the first resin may be semi-cured at a certain temperature for a certain period of time. That is, the second step 220 is a process of semi-curing the first resin instead of completely curing the first resin.

In the third step 230, the color coordinates of the light emitting device having the first resin are measured.

In the fourth step 240, a second resin containing or free from phosphors may be formed on the first resin to correct the color coordinates depending upon the measured color coordinates.

If the color coordinates of the light emitting device deviate from a target bin, the second resin containing or free from phosphors may be formed on the first resin in order to correct the color coordinates.

In the fifth step 250, the first and second resins are cured, thereby completing formation of a wavelength conversion part.

According to this exemplary embodiment, the color coordinates of the light emitting device having the first resin are measured after semi-curing of the first resin, and are corrected using the second resin, thereby improving yield of the light emitting device.

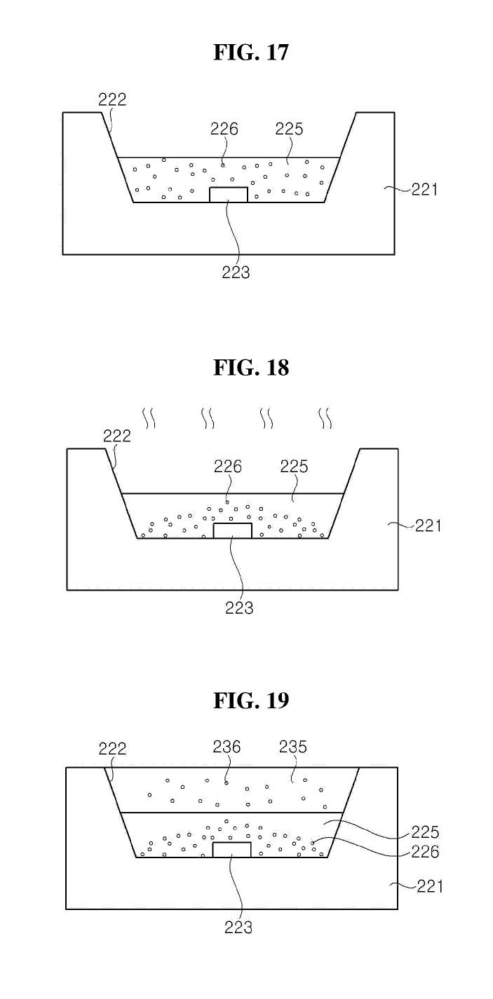

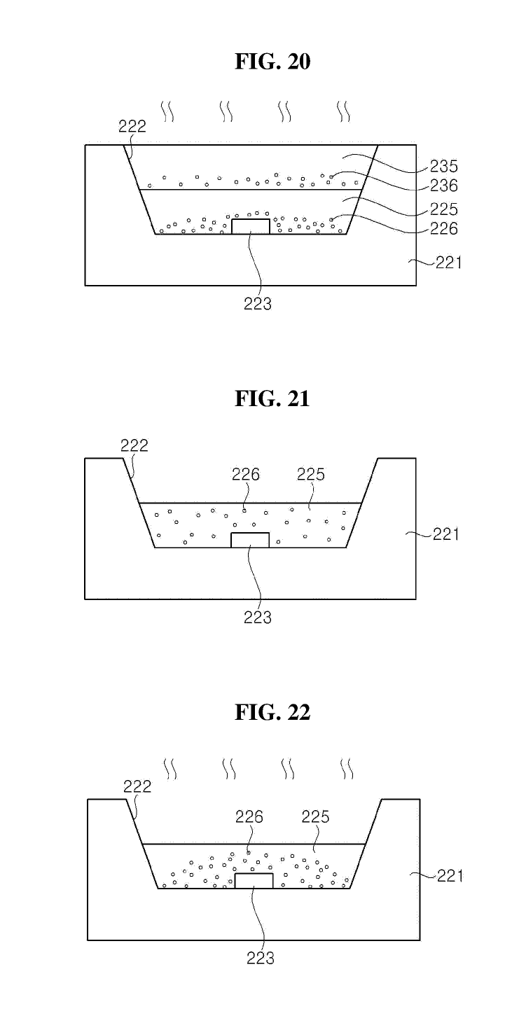

Referring to FIG. 16 and FIG. 17, a first resin 225 is formed on a light emitting diode chip 223 mounted on a package body 221. The package body 221 may have a cavity 222 and the light emitting diode chip 223 may be mounted on a bottom surface of the cavity 222. The package body 221 includes lead electrodes (not shown) and the light emitting diode chip 223 is electrically connected to the lead electrodes.

The first resin 225 may be formed by applying a molding resin containing first phosphors 226 in the cavity 222 of the package body 221 using a dispenser. It should be understood that the first resin 225 can be formed in the cavity using a variety of molding methods. The first resin 225 covers the light emitting diode chip 223.

The first resin 225 is formed to a predetermined height in the cavity 222 and a portion of the cavity 222 is exposed from the first resin 225.

Referring to FIG. 16 and FIG. 18, the first resin 225 is semi-cured at a certain temperature for a certain period of time.

Referring to FIG. 16, FIG. 8 and FIG. 19, a second resin 235 is formed on the semi-cured first resin 225. The second resin 235 contains second phosphors 236 and may be formed on the first resin by applying the molding resin in the cavity 222 of the package body 221 using a dispenser.

If the color coordinates are placed at point A, it is determined that the color coordinates of the light emitting device deviate from a target bin, and the second resin containing the second phosphors 236 is formed on the first resin 225 in order to increase the concentration of the phosphors in the cavity such that the color coordinates can be shifted into the target bin.

Referring to FIG. 16 and FIG. 20, the first resin 225 and the second resin 235 are cured, thereby completing formation of the wavelength conversion part. Here, the first and second phosphors are precipitated after a predetermined period of time. That is, the concentration of the first phosphors 226 gradually decreases towards an upper surface of the first resin 225 and the concentration of the second phosphors 236 gradually decreases towards an upper surface of the second resin 235.

As described above, the color coordinates of the light emitting device are measured after forming the first resin 225 to a predetermined height in the cavity and semi-curing the first resin, and the second resin 235 is formed on the first resin 225 to correct the color coordinates, followed by curing, thereby improving yield of the light emitting device.

Referring to FIG. 16 and FIG. 21, a first resin 225 is formed on a light emitting diode chip 223 mounted on a package body 221.

The first resin 225 is formed of a molding resin containing first phosphors 226 and may be formed by applying the molding resin in the cavity 222 of the package body 221 using a dispenser. It should be understood that the first resin 225 can be formed in the cavity 222 using a variety of molding methods. The first resin 225 covers the light emitting diode chip 223.

The first resin 225 is formed to a predetermined height in the cavity 222 and a portion of the cavity 222 is exposed from the first resin 225.

Referring to FIG. 16 and FIG. 22, the first resin 225 is semi-cured at a certain temperature for a certain period of time.

Referring to FIG. 16, FIG. 8 and FIG. 23, a second resin 235 is formed on the semi-cured first resin 225. The second resin 235 is a molding resin free from phosphors and may be formed on the first resin by applying the molding resin in the cavity 222 of the package body 221 using a dispenser.

If the color coordinates are placed at point B, it is determined that the color coordinates of the light emitting device deviate from a target bin, and the second resin free from the phosphors is formed on the first resin 225 in order to increase the concentration of the phosphors in the cavity 222 such that the color coordinates can be shifted into the target bin.

After correction of the color coordinates, the first resin 225 and the second resin 235 are cured, thereby completing formation of the wavelength conversion part.

As described above, the color coordinates of the light emitting device are measured after forming the first resin 225 to a predetermined height in the cavity and semi-curing the first resin, and the second resin 235 is formed on the first resin 225 to correct the color coordinates, followed by curing, thereby improving yield of the light emitting device.

If the color coordinates measured in the third step 230 are placed at point C or D, a molding resin containing phosphors suitable for correction of the color coordinates may be mixed with the first resin. When the first resin contains two or more kinds of phosphors, the color coordinates can be generally placed at point C or D deviating from the target bin. In this case, the color coordinates may be shifted into the target bin by adjusting the concentration ratio of the phosphors used in the first resin and in the other molding resin or by mixing a different kind of phosphors from the phosphors of the first resin with the phosphors of the first resin.

The method of correcting the color coordinates according to the disclosure can be applied to various light emitting devices. For example, the correction method according to the disclosure may be applied to correction of the color coordinates of a light emitting device including a wavelength conversion part in which phosphors are relatively uniformly distributed in a resin, and to correction of the color coordinates of a light emitting device including a phosphor layer in which phosphors settle in the resin.

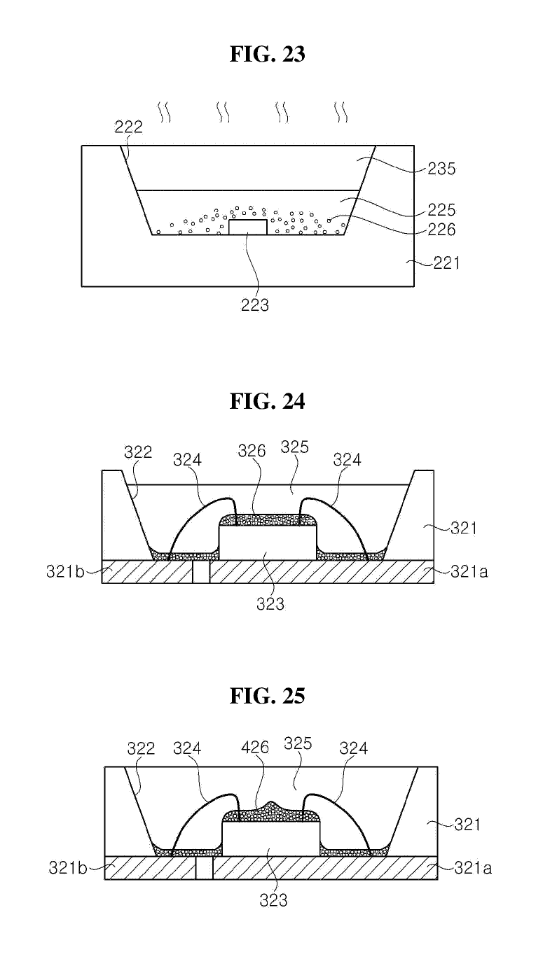

Referring to FIG. 24, the light emitting device according to this exemplary embodiment of the disclosure includes a package body 321 having a cavity 322 therein, lead terminals 321a, 321b, a light emitting diode chip 323, bonding wires 324, a settled phosphor layer 326, and a resin 325.

The package body 321, the lead terminals 321a, 321b and the light emitting diode chip 323 are similar to those of the above exemplary embodiments and thus detailed descriptions thereof will be omitted to avoid repetition. In this exemplary embodiment, the light emitting diode chip 323 may have a horizontal structure and thus two bonding wires 324 electrically connect the light emitting diode chip 323 to the lead terminals 321a, 321b.

The phosphor layer 326 is formed on upper surfaces of the light emitting diode chip 323 and the lead terminals 321a, 321b. The phosphor layer 326 is formed through settlement of phosphors dispersed in the resin. Since the phosphors are agglomerated on the upper surface of the light emitting diode chip 323, there is less movement of the phosphors due to an external factor such as thermal expansion. Therefore, it is possible to prevent generation of color deviation due to a high temperature process for surface mounting.

Further, since the phosphor layer 326 generally has a uniform thickness, light subjected to wavelength conversion depending upon the location of the light emitting diode chip 323 is uniformly emitted, thereby providing low aberration. Since the phosphors are concentrated in a predetermined thickness, a traveling distance of light emitted from the light emitting diode chip 323 to the phosphors is shorter than the traveling distance of light in the wavelength conversion part in which the phosphors are distributed in the resin. Thus, the concentration of the phosphors in the resin for formation of the wavelength conversion part in which the phosphors settle is higher than the concentration of the phosphors in the wavelength conversion part in which the phosphors are distributed. Accordingly, there can be a problem of clogging of a nozzle orifice of the dispenser by the phosphors. In order to prevent this problem, the resin is required to have a low viscosity and may have a viscosity in the range of about 100 mPa·sec to 2,500 mPa·sec. On the other hand, in order to reduce the viscosity of the resin so as to allow more rapid settlement of the phosphors, the resin may have a viscosity in the range of about 100 mPa·sec to 1,500 mPa·sec. Further, like a side-view light emitting diode package having a small size, a light emitting device in which the cavity has a narrow width can suffer from difficulty ejecting a phosphor-containing resin and thus it is necessary to further reduce the viscosity of the resin. In this case, the resin may have a viscosity in the range of 100 mPa·sec to 1000 mPa·sec.

Since the light emitting device according to the exemplary embodiment has color coordinates within a target bin when measured after dispensing the first resin, the resin is cured without correction of the color coordinates. Measurement of the color coordinates can be performed through individual measurement with the aforementioned measurement device simultaneously contacting a plurality of light emitting devices, thereby reducing measurement time. On the other hand, since the resin is cured without correction of the color coordinates, the height of the resin may be placed lower than an upper end of the package body 321 and the settled phosphor layer 326 has a substantially uniform thickness.

Referring to FIG. 25, the light emitting device according to this exemplary embodiment is generally similar to the light emitting device described with reference to FIG. 24 except for the shape of a phosphor layer 426. According to this exemplary embodiment, the color coordinates of the light emitting device are placed at point A as measured after curing the first resin, and a phosphor-containing resin is added for correction of the color coordinates. The phosphor-containing resin is placed in a central region of the light emitting diode chip 323 and thus the phosphor layer 426 has a convex portion in the central region thereof. For correction of the color coordinates, the phosphor-containing resin is ejected to an upper surface of the light emitting diode chip 323, particularly, to a space between the bonding wires 324 in order to prevent influence on the bonding wires 324, using the dispenser. As a result, the convex portion is formed between the bonding wires 324.

In this exemplary embodiment, since the light emitting diode chip 323, to which the two bonding wires are bonded, is used, the convex portion of the phosphor layer 426 is placed between the bonding wires. However, in the structure wherein the light emitting diode chip 323 includes one bonding wire or does not use a bonding wire as in a flip-chip light emitting diode chip, the convex portion may be formed in the central region of the light emitting diode chip 323 so as to provide a symmetrical structure, but is not limited thereto. Alternatively, the convex portion may be formed near an edge of the light emitting diode chip 323.

On the other hand, since the phosphor-containing resin is added, the upper surface of the resin 325 is higher than the upper surface of the resin shown in FIG. 24 and may be flush with the upper surface of the package body 321.

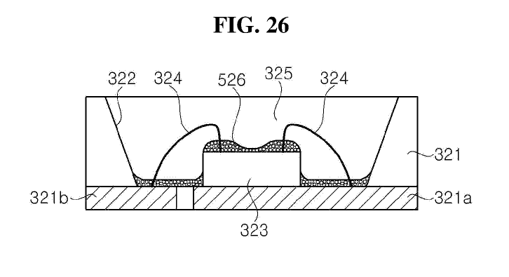

Referring to FIG. 26, the light emitting device according to this exemplary embodiment is generally similar to the light emitting device described with reference to FIG. 24 except for the shape of a phosphor layer 526. According to this exemplary embodiment, the color coordinates of the light emitting device are placed at point B as measured after curing the first resin, and a phosphor-free resin is added for correction of the color coordinates. The phosphor-free resin is placed in a central region of the light emitting diode chip 323 and pushes phosphors placed in the central region of the light emitting diode chip 323 towards the outside. As a result, the phosphor layer has a concave portion in the central region of the light emitting diode chip 323. For correction of the color coordinates, the resin is ejected to an upper surface of the light emitting diode chip 323, particularly, to a space between the bonding wires 324 in order to prevent influence on the bonding wires 324, using the dispenser. As a result, the concave portion is formed between the bonding wires 324.

In this exemplary embodiment, since the light emitting diode chip 323, to which the two bonding wires are bonded, is used, the concave portion of the phosphor layer 426 is formed between the bonding wires. However, in the structure wherein the light emitting diode chip 323 includes one bonding wire or does not use a bonding wire as in a flip-chip light emitting diode chip, the concave portion may be formed in the central region of the light emitting diode chip 323 so as to provide a symmetrical structure, but is not limited thereto. Alternatively, the concave portion may be formed near an edge of the light emitting diode chip 323.

Although some exemplary embodiments have been disclosed with reference to the drawings, it should be understood that the above exemplary embodiments are provided for illustration only and do not limit the disclosure, and that various modifications, changes, and alterations can be made by those skilled in the art without departing from the spirit and scope of the disclosure.

What is claimed is:

1. A color coordinate measuring apparatus comprising:
a rail on which a substrate is mounted, the substrate having a plurality of light emitting devices (LEDs) formed thereon;
a transfer device disposed under the rail and configured to move toward or away from a target region of the substrate;
a plurality of electrode pins disposed on the transfer device and configured to respectively contact electrodes of the plurality of LEDs in the target region at the same time when the transfer device approaches the target region;
a controller configured to sequentially supply electric power to the plurality of electrode pins; and
a measurement unit disposed above the rail and configured to be placed above the target region in which the plurality of electrode pins is brought into contact with the electrodes of the light emitting devices.

2. The color coordinate measuring apparatus according to claim 1, wherein the electrodes of the LEDs are downward exposure type electrodes, and are configured such that, as the transfer device approaches the electrodes in an upward direction from a place below the electrodes, the electrode pins simultaneously contact respective electrodes of the LEDs in the target region.

3. The color coordinate measuring apparatus according to claim 1, wherein the electrodes of the LEDs are lateral exposure type electrodes, and are configured such that, as the transfer device approaches the substrate in an upward direction from a place below the substrate and is then moved in a lateral direction, the electrode pins simultaneously contact respective electrodes of the LEDs in the target region.

4. The color coordinate measuring apparatus according to claim 3, wherein the transfer device is provided with a contact block supporting a lower surface of the substrate to prevent the substrate from sagging when the transfer device approaches the substrate in the upward direction from the place below the substrate, such that the lateral exposure type electrodes are aligned with the electrode pins.

5. The color coordinate measuring apparatus according to claim 2, wherein each of the electrode pins is independently elastically supported in the upward direction.

6. The color coordinate measuring apparatus according to claim 3, wherein each of the electrode pins is independently elastically supported in the lateral direction.

7. The color coordinate measuring apparatus according to claim 1, wherein the plurality of electrode pins constitutes a conversion module such that the electrode pins are detachably attached to the transfer device.

8. The color coordinate measuring apparatus according to claim 4, wherein the plurality of electrode pins and the contact blocks constitute a conversion module such that the electrode pins are detachably attached to the transfer device.

9. The color coordinate measuring apparatus according to claim 7, wherein the transfer device is provided with a base part to which the conversion module is detachably attached, the base part being provided with a printed circuit board (PCB) configured to distribute electric current to each of the electrode pins.

10. The color coordinate measuring apparatus according to claim 1, wherein the transfer device is configured to be transferred in an x-direction parallel to a surface of the substrate, in a y-direction parallel to the surface of the substrate and perpendicular to the x-direction, and in a z-direction perpendicular to the surface of the substrate.

11. The color coordinate measuring apparatus according to claim 1, wherein the measurement unit is configured to be transferred in the x-direction parallel to the surface of the substrate and in the y-direction parallel to the surface of the substrate and perpendicular to the x-direction.

12. A color coordinate measurement method comprising:
mounting a substrate on a rail, the substrate having a plurality of LEDs formed thereon;
placing a measurement unit above a plurality of LEDs in a target region to be measured;
bringing a plurality of electrode pins into contact with electrodes of the plurality of LEDs in the target region by moving the plurality of electrode pins upwards from a place below the plurality of LEDs in the target region to be measured;
sequentially measuring color coordinates of the plurality of LEDs in the target region by sequentially supplying electric power to each of the plurality of electrode pins; and
correcting the color coordinates of an LED deviating from a target bin based on the measured color coordinates of each of the LEDs.

13. The color coordinate measurement method according to claim 12, wherein correction of the color coordinates comprises adding a phosphor-containing resin to the LED deviating from the target bin.

14. The color coordinate measurement method according to claim 12, wherein correction of the color coordinates comprises adding a phosphor-free resin to the LED deviating from the target bin.

15. A light emitting device comprising:
a package body having a cavity therein;
a light emitting diode chip mounted in the cavity;
a resin covering the light emitting diode chip in the cavity; and
a phosphor layer placed in the resin and settled on the light emitting diode chip,
wherein the phosphor layer has a convex portion or a concave portion on the light emitting diode chip.

16. The light emitting device according to claim 15, wherein the concave portion or the convex portion is in a central region of the light emitting diode chip.

17. The light emitting device according to claim 16, further comprising:
at least two bonding wires bonded to the light emitting diode chip,
wherein the concave portion or the convex portion is between the bonding wires.

18. A color coordinate correction system comprising:
the color coordinate measuring apparatus of claim 1 configured to measure color coordinates of a plurality of light emitting devices formed on a substrate; and
dispensers configured to respectively eject a phosphor-containing resin and a phosphor-free resin to a light emitting device deviating from a target bin based on color coordinates measured by the measurement unit.
